(19) United States
(12) Patent Application Publication
(10) Pub. No.: US 2024/0321343 A1
(43) Pub. Date: Sep. 26, 2024

(54) MEMORY DEVICE USING SEMICONDUCTOR ELEMENT

(71) Applicant: Unisantis Electronics Singapore Pte. Ltd., Singapore (SG)

(72) Inventors: Koji SAKUI, Tokyo (JP); Yoshihisa IWATA, Tokyo (JP); Masakazu KAKUMU, Tokyo (JP); Nozomu HARADA, Tokyo (JP)

(21) Appl. No.: 18/609,198

(22) Filed: Mar. 19, 2024

(30) Foreign Application Priority Data
Mar. 23, 2023 (WO) PCT/JP2023/011529

(51) Int. Cl. G11C 11/4096; G11C 5/06; G11C 11/4094; H10B 12/00

(52) U.S. Cl. CPC G11C 11/4096; G11C 5/063; G11C 11/4094; H10B 12/20; H10B 12/50

(57) ABSTRACT

In a memory device, a page is composed of memory cells arranged in rows, and pages are arranged in columns in plan view on a substrate. Each memory cell has a semiconductor base, a first impurity layer and a second impurity layer at both ends in an extension direction of the semiconductor base, and at least two (first and second) gate conductor layers. The first impurity layer is connected to a source line, the second impurity layer to a bit line, one of the first or second gate conductor layer to a selection gate line, and the other to a plate line. Voltages applied to the source line, bit line, selection gate line, and plate line are controlled to perform page erasing and writing operations. A hole group formed by impact ionization is retained within the semiconductor base to have logic storage data that is at least three-valued.

### CROSS-REFERENCE TO RELATED APPLICATIONS

This application claims priority to PCT/JP2023/011529, filed Mar. 23, 2023, the entire content of which is incorporated herein by reference.

### BACKGROUND OF THE INVENTION

### 1. Field of the Invention

The present invention relates to a memory device using a semiconductor element.

### 2. Description of the Related Art

In recent years, in the development of large scale integration (LSI) technology, higher integration and higher performance of memory elements are demanded.

Achieving higher density and higher performance of memory elements are in progress. The following are some examples: using a surrounding gate transistor (SGT; see Japanese Unexamined Patent Application Publication No. H2-188966, and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)) as a selection transistor, a dynamic random access memory (DRAM) connected with a capacitor (for example, see H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference (2011)); a phase change memory (PCM) connected with a resistance change element (see, for example, H. S. Phillip Wong, S. Raoux, S. Kim, Jiale Liang, J. R. Reifenberg, B. Rajendran, M. Asheghi, and K. E. Goodson: “Phase Change Memory,” Proceeding of IEEE, Vol. 98, No. 12, December, pp. 2201-2227 (2010)); a resistive random access memory (RRAM) (see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3V,” IEDM (2007)); and a magneto-resistive random access memory (MRAM) that changes the direction of the magnetic spin by current to change the resistance (see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)).

Furthermore, there is also a DRAM memory cell composed of a single MOS transistor without a capacitor (see Japanese Unexamined Patent Application Publication No. H3-171768; M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010); J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, and A. Nitayama: “Floating Body RAM Technology and its Scalability to 32 nm Node and Beyond,” IEEE IEDM (2006); and E. Yoshida and T. Tanaka: “A Design of a Capacitorless 1T-DRAM Cell Using Gate-induced Drain Leakage (GIDL) Current for Low-power and High-speed Embedded Memory,” IEEE IEDM, pp. 913-916 (2003)). For example, of a group of holes and a group of electrons generated by the phenomenon of impact ionization within the channel caused by the source-drain current of an N-channel MOS transistor, the hole group is retained, either partially or entirely, within the channel to perform writing of the logic storage data “1”. Then, the hole group is discharged from the channel to write the logic storage data “0”. This memory cell has a common selection word line, for which there are randomly “1” written memory cells and “0” written memory cells. In response to application of an on-voltage to the selection word line, a selected memory cell connected to the selection word line has a floating body channel voltage that fluctuates greatly due to the capacitive coupling between the gate electrode and the channel. For this memory cell, it is an issue to improve the reduction of the operating margin due to the voltage fluctuation of the floating body channel, and to improve the reduction of the data retention characteristics caused by discharging a portion of the group of holes, which are signal charges stored in the channel.

In addition, there is a twin-transistor MOS transistor memory element in which one memory cell is formed using two MOS transistors on a SOI layer (see, for example, US 2008/0137394 A1, US 2003/0111681 A1, and F. Morishita, H. Noda, I. Hayashi, T. Gyohten, M. Okamoto, T. Ipposhi, S. Maegawa, K. Dosaka, and K. Arimoto: “Capacitorless Twin-Transistor Random Access Memory (TTRAM) on SOI,” IEICE Trans. Electron., Vol. E90-c., No. 4 pp. 765-771 (2007)). In such elements, an N⁺ layer serving as the source or drain to separate the floating body channels of the two MOS transistors is formed in contact with an insulating layer on the substrate side. This N⁺ layer electrically isolates the floating body channels of the two MOS transistors. A group of holes, which are signal charges, is stored only in the floating body channel of one MOS transistor. The other MOS transistor becomes a switch for reading out the group of holes, which are signals stored in one MOS transistor. For this memory cell as well, because the group of holes, which are signal charges, is stored in the channel of one MOS transistor, like the aforementioned memory cell consisting of one MOS transistor, it is an issue to improve the reduction of the operating margin or to improve the reduction of the data retention characteristics caused by discharging a portion of the group of holes, which are signal charges stored in the channel.

A dynamic flash memory (DFM) cell 111, illustrated in FIGS. 6A to 6D, consisting of a MOS transistor without a capacitor is also available (see Japanese Patent Publication No. 7057032, and K. Sakui and N. Harada, “Dynamic Flash Memory with Dual Gate Surrounding Gate Transistor (SGT),” Proc. IEEE IMW, pp. 72-75 (2021)). As illustrated in FIG. 6A, there is a floating body semiconductor base 102 on a SiO₂ layer 101 of the SOI substrate. At both ends of the floating body semiconductor base 102, there are an N⁺ layer 103 connected to a source line SL and an N⁺ layer 104 connected to a bit line BL. Then, there are a first gate insulating layer 109a connected to the N⁺ layer 103 and covering the floating body semiconductor base 102, and a second gate insulating layer 109b connected to the N⁺ layer 104 and to the first gate insulating layer 109a via a slit insulating film 110 and covering the floating body semiconductor base 102. Then, there are a first gate conductor layer 105a covering the first gate insulating layer 109a and connected to a plate line PL, and a second gate conductor layer 105b covering the second gate insulating layer 109b and connected to a word line WL. Then, there is the slit insulating film 110 between the first gate conductor layer 105a and the second gate conductor layer 105b. This forms the memory cell 111 of the DFM. Note that it is acceptable to configure the source line SL to connect to the N⁺ layer 104 and the bit line BL to the N⁺ layer 103.

Then, as illustrated in FIG. 6A, for example, a zero voltage is applied to the N⁺ layer 103 and a positive voltage is applied to the N⁺ layer 104 to allow a first N-channel MOS transistor region consisting of the floating body semiconductor base 102 covered with the first gate conductor layer 105a to operate in a saturated region and a second N-channel MOS transistor region consisting of the floating body semiconductor base 102 covered with the second gate conductor layer 105b to operate in a linear region. As a result, there is no pinch-off point in the second N-channel MOS transistor region, forming an inversion layer 107b across the entire surface. The inversion layer 107b formed below the second gate conductor layer 105b connected with the word line WL operates as a substantial drain of the first N-channel MOS transistor region. As a result, the electric field is maximized in the boundary region of the channel region between the first N-channel MOS transistor region and the second N-channel MOS transistor region, and the phenomenon of impact ionization occurs in this region. Then, as illustrated in FIG. 6B, a memory writing operation is performed by discharging, of a group of electrons and a group of holes generated by the phenomenon of impact ionization, the electron group from the floating body semiconductor base 102 and retaining a hole group 106, either partially or entirely, within the floating body semiconductor base 102. This state becomes the logic storage data “1”.

Then, as illustrated in FIG. 6C, for example, a positive voltage is applied to the plate line PL, a zero voltage to the word line WL and the bit line BL, and a negative voltage to the source line SL, thus discharging the hole group 106 from the floating body semiconductor base 102 to perform an erasing operation. This state becomes the logic storage data “0”. Then, in the data readout, by setting the voltage applied to the first gate conductor layer 105a connected to the plate line PL to be higher than a threshold voltage at the time of the logic storage data “1” and lower than a threshold voltage at the time of the logic storage data “0”, the characteristics that no current flows even if the voltage of the word line WL is increased in reading out the logic storage data “0” as illustrated in FIG. 6D are obtained. Due to these characteristics, the operating margin is significantly increased as compared to a DRAM memory cell composed of a single MOS transistor without a capacitor. In this memory cell, because the channels of the first and second N-channel MOS transistor regions, having the first gate conductor layer 105a connected to the plate line PL and the second gate conductor layer 105b connected to the word line WL as gates, are connected by the floating body semiconductor base 102, the voltage fluctuation of the floating body semiconductor base 102 when a selection pulse voltage is applied to the word line WL is greatly suppressed. This greatly improves the aforementioned issue of reduction of the operating margin in the memory cell, or the reduction of the data retention characteristics due to discharging a portion of the group of holes, which are signal charges stored in the channel. In the future, further improvement of the characteristics of the memory element is demanded.

### SUMMARY OF THE INVENTION

In a dynamic flash memory cell, a refresh operation for retaining logic data in the memory cell is required.

To solve the above-described issue, a first invention is a memory device in which, in plan view on a substrate, a page is composed of a plurality of memory cells arranged in a row direction, and a plurality of pages are arranged in a column direction. Each memory cell included in each page includes: a semiconductor base that, on the base, stands vertically or extends horizontally with respect to the substrate; a first impurity layer and a second impurity layer connected to both ends in an extension direction of the semiconductor base; a gate insulating layer surrounding the semiconductor base; and a first gate conductor layer and a second gate conductor layer that cover the gate insulating layer and that are arranged side by side. The first impurity layer is connected to a source line, the second impurity layer is connected to a bit line, one of the first gate conductor layer or the second gate conductor layer is connected to a selection gate line, and the other is connected to a plate line. Voltages applied to the source line, the bit line, the selection gate line, and the plate line are controlled to perform a page erasing operation and a page writing operation. Within the semiconductor base, a hole group formed by an impact ionization phenomenon is retained. Logic storage data that is at least three-valued is written and read.

A second invention is characterized in that, in the first invention described above, the selection gate line includes a first selection gate line and a second selection gate line, and the first selection gate line and the second selection gate line hold the plate line therebetween.

A third invention is characterized in that, in the first invention described above, the logic storage data is four-valued.

A fourth invention is characterized in that, in the first invention described above, the voltage of the bit line is gradually increased during the page writing operation.

A fifth invention is characterized in that, in the first invention described above, the voltage of one or both of the selection gate line and the plate line is gradually increased during the page writing operation.

A sixth invention is characterized that, in the third invention described above, the logic storage data which is four-valued is assigned in an order of “10”, “11”, “01”, and “00”, starting from a lower threshold voltage of the selection gate line.

### BRIEF DESCRIPTION OF THE DRAWINGS

FIG. 1 is a structural diagram of a semiconductor memory device according to a first embodiment;

FIGS. 2A, 2B, and 2C are diagrams for explaining an erasing operation mechanism of the semiconductor memory device according to the first embodiment;

FIGS. 3A, 3B, and 3C are diagrams for explaining a writing operation mechanism of the semiconductor memory device according to the first embodiment;

FIGS. 4A, 4B, and 4C are diagrams for explaining a reading operation mechanism of the semiconductor memory device according to the first embodiment;

FIG. 5 is a structural diagram of the semiconductor memory device according to the first embodiment; and

FIGS. 6A, 6B, 6C, and 6D are diagrams for explaining a dynamic flash memory of the related art.

### DESCRIPTION OF THE PREFERRED EMBODIMENTS

Hereinafter, a memory device using a semiconductor element (which is an example of a “memory device” of the claims and referred to hereinafter as dynamic flash memory) according to an embodiment of the present invention will be described with reference to the drawings.

### First Embodiment

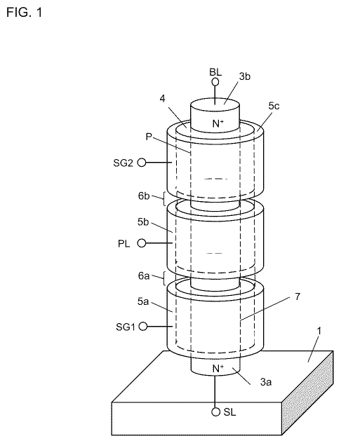

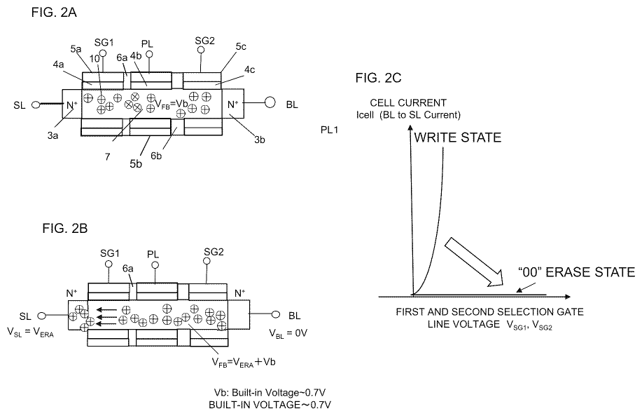

Using FIGS. 1 to 4C, the structure and operating mechanisms of a dynamic flash memory cell (which is an example of a “memory cell” of the claims) according to a first embodiment of the present invention will be described. The structure of a dynamic flash memory cell will be described using FIG. 1. Then, a page erasing operation, a page writing operation, and a page reading operation will be described using FIGS. 2A to 4C.

FIG. 1 illustrates the structure of a dynamic flash memory cell according to the first embodiment of the present invention. On a substrate 1 (which is an example of a “substrate” of the claims), the following layers are arranged from bottom to top: an N⁺ layer 3a (which is an example of a “first impurity layer” of the claims); a semiconductor base 7 (which is an example of a “semiconductor base” of the claims; hereinafter, a semiconductor region containing acceptor impurity will be referred to as a “P layer”); and an N⁺ layer 3b (which is an example of a “second impurity layer” of the claims). The pillar-shaped P layer 7 is surrounded by a gate insulating layer 4. Then, the gate insulating layer 4 is surrounded by, from bottom to top, a first gate conductor layer 5a (which is an example of a “first gate conductor layer” of the claims), a second gate conductor layer 5b (which is an example of a “second gate conductor layer” of the claims), and a third gate conductor layer 5c (which is an example of a “third gate conductor layer” of the claims). Then, the first gate conductor layer 5a and the second gate conductor layer 5b are isolated by an insulating layer 6a, and the second gate conductor layer 5b and the third gate conductor layer 5c are isolated by an insulating layer 6b. This forms a dynamic flash memory cell composed of the N⁺ layers 3a and 3b, the pillar-shaped P layer 7, the gate insulating layer 4, the first gate conductor layer 5a, the second gate conductor layer 5b, and the third gate conductor layer 5c. A region of the semiconductor base 7 between a first N-channel MOS transistor region surrounded by the first gate conductor layer 5a and a second N-channel MOS transistor region surrounded by the second gate conductor layer 5b is referred to as a first boundary region, and a region of the pillar-shaped P layer 7 between the second N-channel MOS transistor region and a third N-channel MOS transistor region surrounded by the third gate conductor layer 5c is referred to as a second boundary region.

As illustrated in FIG. 1, the N⁺ layer 3a is connected to a source line SL (which is an example of a “source line” of the claims), the N⁺ layer 3b to a bit line BL (which is an example of a “bit line” of the claims), the first gate conductor layer 5a to a first selection gate line SG1 (which is an example of a “first selection gate line” of the claims), the second gate conductor layer 5b to a plate line PL (which is an example of a “plate line” of the claims), and the third gate conductor layer 5c to a second selection gate line SG2 (which is an example of a “second selection gate line” of the claims).

It is desirable to have a structure such that the gate capacitance of the first gate conductor layer 5a connected to the first selection gate line SG1 and the second gate conductor layer 5b connected to the plate line PL is larger than the gate capacitance of the third gate conductor layer 5c connected to the second selection gate line SG2.

Also, any or all of the first gate conductor layer 5a, the second gate conductor layer 5b, and the third gate conductor layer 5c may be divided into two or more portions in plan view, and these portions may respectively be operated synchronously or asynchronously as conductive electrodes of the first selection gate line, the plate line, and the second selection gate line. This also results in dynamic flash memory operations. Also, one of the divided portions of the individual conductor layers may be connected in plan view.

Also, a gate conductor layer connected to at least one or more plate lines PL may be provided, in addition to the second gate conductor layer 5b. Each of them may be operated synchronously or asynchronously as a conductive electrode of the plate line(s). This also results in dynamic flash memory operations.

Furthermore, the first gate conductor layer 5a, the second gate conductor layer 5b, and the third gate conductor layer 5c are composed of the same material. By composing them with the same material in this way, they can be easily manufactured in terms of processing.

Also, a dynamic flash memory may be configured with either the first selection gate line or the second selection gate line in FIG. 1 removed. In this case, the dynamic flash memory is controlled by the first gate conductor layer 5a and the second gate conductor layer 5b, which are two gate conductor layers of the selection gate line (which is an example of a “selection gate line” of the claims) and the plate line.

Using FIGS. 2A to 2C, a mechanism of a page erasing operation (which is an example of a “page erasing operation” of the claims) will be described. Actually, in plan view on the substrate, a page (which is an example of a “page” of the claims) is composed of multiple memory cells arranged in the row direction, and multiple pages are arranged in the column direction, thus constituting a memory device. In this example, a page erasing operation of one memory cell among these memory cells will be described. The semiconductor base 7 between the N⁺ layers 3a and 3b is electrically isolated from the substrate 1 and serves as a floating body. FIG. 2A illustrates a state in which, before a page erasing operation, a hole group 10 generated by impact ionization in the previous cycle is stored in the semiconductor base 7. Then, as illustrated in FIG. 2B, during the page erasing operation, the voltage of the source line SL is set to a negative voltage V_{ERA}. Here, V_{ERA} is, for example, −1.5 V. As a result, regardless of the initial potential value of the semiconductor base 7, the PN junction between the N⁺ layer 3a, serving as the source connected with the source line SL, and the semiconductor base 7 becomes forward-biased. As a result, the hole group 10 stored in the semiconductor base 7, which is generated by impact ionization in the previous cycle, is drawn into the N⁺ layer 3a of the source part, and the potential V_{FB} of the semiconductor base 7 becomes a voltage near V_{ERA}+Vb. Here, Vb is the built-in voltage of the PN junction and is about 0.7 V. Thus, in the case where V_{ERA}=−1.5 V, the potential of the semiconductor base 7 is −0.8 V. This value becomes the potential state of the semiconductor base 7 in the erase state. Therefore, when the potential of the floating-body semiconductor base 7 becomes a negative voltage, the threshold voltage of the N-channel MOS transistor region of the dynamic flash memory cell increases due to substrate bias effects. Thus, the threshold voltages of the first gate conductor layer 5a connected to the first selection gate line SG1, the second gate conductor layer 5b connected to the plate line PL, and the third gate conductor layer 5c connected to the second selection gate line SG2 increase. Accordingly, as illustrated in FIG. 2C, a cell current Icell becomes zero on the graph with the voltage of the first selection gate line SG1 and the second selection gate line SG2 plotted on the x-axis. The erase state of the semiconductor base 7 becomes the logic storage data (which is an example of “logic storage data” of the claims) “00”. Note that the conditions of voltages applied to the bit line BL, the source line SL, the first selection gate line SG1, the plate line PL, and the second selection gate line SG2 described above, and the potential of the floating body are examples for performing a page erasing operation, and may be other operating conditions under which an erasing operation can be performed.

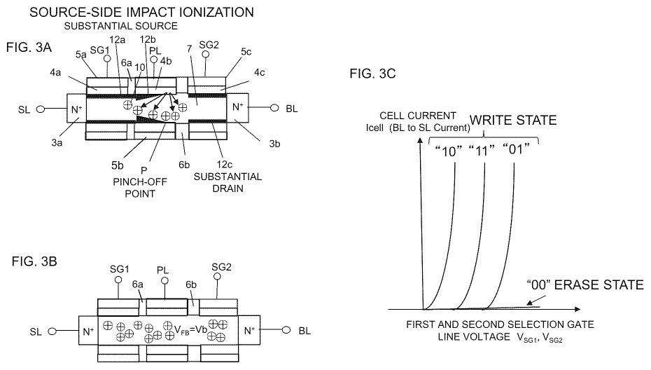

FIGS. 3A to 3C illustrate a page writing operation (an example of a “page writing operation” of the claims) of the dynamic flash memory cell. As illustrated in FIG. 3A, for example, 0 V is input to the N⁺ layer 3a connected with the source line SL; for example, 0.6 V is input to the N⁺ layer 3b connected with the bit line BL; for example, 2 V is input to the first gate conductor layer 5a connected to the first selection gate line SG1 and to the third gate conductor layer 5c connected to the second selection gate line SG2; and, for example, 1.5 V is input to the second gate conductor layer 5b connected to the plate line PL. As a result, as illustrated in FIG. 3A, ring-shaped inversion layers 12a and 12c are formed on the semiconductor base 7 inside the first gate conductor layer 5a connected with the first selection gate line SG1, and the third gate conductor layer 5c connected with the second selection gate line SG2. As a result, the first N-channel MOS transistor region having the first gate conductor layer 5a and the third N-channel MOS transistor region having the third gate conductor layer 5c are operated in, for example, a linear region. In the meantime, the second N-channel MOS transistor region having the second gate conductor layer 5b connected with the plate line PL is operated in, for example, a saturated region. As a result, there is a pinch-off point P in the inversion layer 12b. In this case, the inversion layers 12a and 12c, which are formed on the entire surface inside the first gate conductor layer 5a connected with the first selection gate line SG1 and inside the third gate conductor layer 5c connected with the second selection gate line SG2, respectively operate as a substantial source and drain of the second N-channel MOS transistor region having the second gate conductor layer 5b connected with the plate line PL.

As a result, the electric field is maximized in the second boundary region of the semiconductor base 7 between the second N-channel MOS transistor region and the third N-channel MOS transistor region, which are connected in series, and the phenomenon of impact ionization occurs in this region. Since this region is the source-side region as seen from the third N-channel MOS transistor region having the third gate conductor layer 5c connected with the second selection gate SG2, this phenomenon is referred to as the phenomenon of source-side impact ionization. Due to this phenomenon of source-side impact ionization, electrons flow from the N⁺ layer 3a connected with the source line SL to the N⁺ layer 3b connected with the bit line BL. The accelerated electrons collide with Si lattice atoms, generating electron-hole pairs due to their kinetic energy. Some of the generated electrons flow into the first gate conductor layer 5a, the second gate conductor layer 5b, and the third gate conductor layer 5c, but the majority flow into the N⁺ layer 3b connected with the bit line BL. Also, in writing, electron-hole pairs may be generated using a gate-induced drain leakage (GIDL) current, and the floating body FB may be filled with the generated hole group (see, for example, E. Yoshida and T. Tanaka, 2003).

Then, as illustrated in FIG. 3B, the generated hole group 10 constitutes majority carriers in the semiconductor base 7, charging the semiconductor base 7 positively. Since the N⁺ layer 3a connected with the source line SL is at 0 V, the semiconductor base 7 is charged to the vicinity of the built-in voltage Vb (about 0.7 V) of the PN junction between the N⁺ layer 3a connected with the source line SL and the semiconductor base 7. When the semiconductor base 7 is charged positively, the threshold voltages of the first N-channel MOS transistor region, the second N-channel MOS transistor region, and the third N-channel MOS transistor region decrease due to substrate bias effects. Accordingly, as illustrated in FIG. 3C, the cell current Icell, plotted on the y-axis, flows on the graph with the voltage of the first selection gate line SG1 and the second selection gate line SG2 plotted on the x-axis. This write state of the semiconductor base 7 is assigned to the logic storage data “01”.

Next, the voltage applied to the N⁺ layer 3b connected with the bit line BL is raised, for example, from 0.6 V to 0.8 V. As a result, the phenomenon of impact ionization in the second boundary region further increases, and the generated hole group 10 further charges the semiconductor base 7 positively. This write state of the semiconductor base 7 is assigned to the logic storage data “11”, as illustrated in FIG. 3C.

Next, the voltage applied to the N⁺ layer 3b connected with the bit line BL is raised, for example, from 0.8 V to 1.0 V. As a result, the phenomenon of impact ionization in the second boundary region further increases, and the generated hole group 10 further charges the semiconductor base 7 positively. This write state of the semiconductor base 7 is assigned to the logic storage data “10”, as illustrated in FIG. 3C.

As illustrated in FIG. 3C, the logic storage data is assigned in the order of “10”, “11”, “01”, and “00”, starting from a lower threshold voltage (which is an example of a “threshold voltage” of the claims) of the first selection gate line SG1 and the second selection gate line SG2. If the logic storage data is assigned in the order of “11”, “10”, “01”, and “00”, a change of the logic storage data from “01” to “01” results in a 2-bit error; to avoid this, the logic storage data is assigned in the order of “10”, “11”, “01”, and “00”, starting from a lower threshold voltage.

Note that, at the time of a page writing operation, electron-hole pairs may be generated by the phenomenon of impact ionization or the GIDL current in, instead of the aforementioned second boundary region, the first boundary region of the semiconductor base 7 between the first N-channel MOS transistor region and the second N-channel MOS transistor region, and the semiconductor base 7 may be charged with the generated hole group 10. Alternatively, electron-hole pairs may be generated by the phenomenon of impact ionization or the GIDL current in a boundary region between the N⁺ layer 3a and the semiconductor base 7 or in a boundary region between the N+ layer 3b and the semiconductor base 7, and the semiconductor base 7 may be charged with the generated hole group 10. Note that the conditions of voltages applied to the bit line BL, the source line SL, the first selection gate line SG1, the plate line PL, and the second selection gate line SG2 described above are examples for performing a page writing operation, and may be other voltage conditions under which a page writing operation can be performed. For example, at the time of a page writing operation, the voltage of one or both of the selection gate line and the plate line may be gradually increased, and the page writing operation may be performed in the order of “01”, “11”, and “10”.

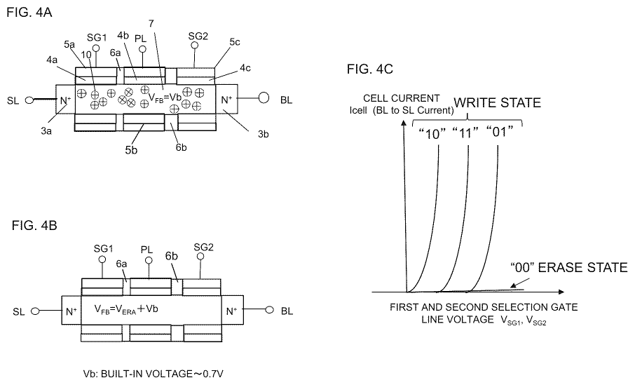

Using FIGS. 4A to 4C, a page reading operation of the dynamic flash memory cell will be described. As illustrated in FIG. 4A, when the semiconductor base 7 is charged to the built-in voltage Vb (about 0.7 V), the threshold voltage decreases due to substrate bias effects. This state is assigned in the order of the logic storage data “10”, “11”, and “01”. As illustrated in FIG. 4B, if a memory block selected before writing is performed is already in the erase state “00”, the floating voltage V_{FB} of the semiconductor base 7 is V_{ERA}+Vb. The writing operation stores the write states “10”, “11”, and “01” in randomly selected cells. As a result, four-valued logic storage data, “00”, “10”, “11”, and “01”, are created for the first and second selection gate lines and SG1 and SG2. As illustrated in FIG. 4C, reading is performed by a sense amplifier circuit utilizing the high-low differences in four threshold voltages for the first and second selection gate lines SG1 and SG2.

The four-valued logic storage data is determined by the bisection method. That is, for example, the intermediate voltage of the four values “10”, “11”, “01”, and “00”, i.e., the intermediate voltage of the threshold voltages of “11” and “01”, is applied to the first and second selection gate lines SG1 and SG2, and it is determined whether the logic storage data of the selected memory cell belongs to the “10” and “11” group or the “01” and “00” group. Then, the intermediate voltage of “10” and “11” or the intermediate voltage of “01” and “00” is applied to the first and second selection gate lines SG1 and SG2, and finally the four-valued logic storage data “10”, “11”, “01”, and “00” are determined.

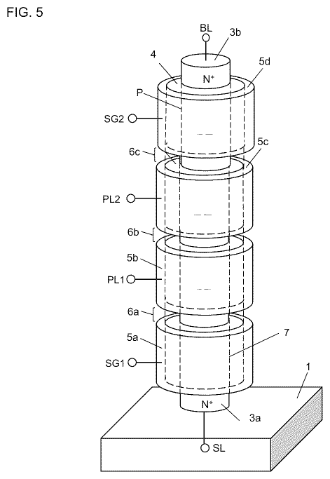

FIG. 5 illustrates a structural diagram in which the plate line PL consists of at least two plate lines PL1 and PL2. Even with such a structure, the dynamic flash memory operations described in the present embodiment can be performed. On the substrate 1, there is a silicon semiconductor pillar (hereinafter a silicon semiconductor pillar may be referred to as a “Si pillar”). From bottom to top, there are the N⁺ layer 3a, the semiconductor base 7, which is a P layer, and the N⁺ layer 3b. The semiconductor base 7, which is a P layer, between the N⁺ layers 3a and 3b becomes a channel. The semiconductor base 7, which is a P layer, is surrounded by the gate insulating layer 4. Then, the gate insulating layer 4 is surrounded by, from bottom to top, the first gate conductor layer 5a, the second gate conductor layer 5b, the third gate conductor layer 5c, and a fourth gate conductor layer 5d. Then, the first gate conductor layer 5a and the second gate conductor layer 5b are isolated by the insulating layer 6a; the second gate conductor layer 5b and the third gate conductor layer 5c are isolated by the insulating layer 6b; and the third gate conductor layer 5c and the fourth gate conductor layer 5d are isolated by an insulating layer 6c. This forms a dynamic flash memory cell composed of the N⁺ layers 3a and 3b, the semiconductor base 7, which is a P layer, the gate insulating layer 4, the first gate conductor layer 5a, the second gate conductor layer 5b, the third gate conductor layer 5c, and the fourth gate conductor layer 5d. Then, as illustrated in FIG. 5, the N⁺ layer 3a is connected to the source line SL, the N⁺ layer 3b to the bit line BL, the first gate conductor layer 5a to the first selection gate line SG1, the second gate conductor layer 5b to the first plate line PL1, the third gate conductor layer 5c to the second plate line PL2, and the fourth gate conductor layer 5d to the second selection gate line SG2.

In FIG. 1 and FIG. 5, the horizontal cross-sectional shape of the Si pillar 7, whether circular, elliptical, or rectangular, allows for the dynamic flash memory operations described in the present embodiment to be performed. Furthermore, circular, elliptical, and rectangular dynamic flash memory cells may be mixed on the same chip.

In FIG. 1, the dynamic flash memory element has been discussed using an SGT by way of example, the SGT including the gate insulating layer 4 surrounding the entire side surface of the Si pillar 7 standing vertically on the substrate, along with the first gate conductor layer 5a, the second gate conductor layer 5b, and the third gate conductor layer 5c surrounding the entire gate insulating layer 4. As described in the explanation of the present embodiment, it is acceptable for the dynamic flash memory element to have any structure as long as it satisfies the condition where the hole group 10 generated by the phenomenon of impact ionization is retained within the semiconductor base 7. To do so, simply the semiconductor base 7 may have a floating body structure isolated from the substrate 1. Accordingly, for example, the aforementioned dynamic flash memory operations can be performed even if the semiconductor base in the channel region is formed to be horizontal with respect to the substrate 1 using one type of SGT, namely, gate all around (GAA; see, for example, J. Y. Song, W. Y. Choi, J. H. Park, J. D. Lee, and B-G. Park: “Design Optimization of Gate-All-Around (GAA) MOSFETS,” IEEE Trans. Electron Devices, vol. 5, no. 3, pp. 186-191, (2006)) technology, or nanosheet technology (see, for example, N. Loubet, et al.: “Stacked Nanosheet Gate-All-Around Transistor to Enable Scaling Beyond FinFET,” 2017 IEEE Symposium on VLSI Technology Digest of Technical Papers, T17-5, T230-T231, (2017)). It may also be acceptable to configure a device structure using silicon on insulator (SOI) (see, for example, J. Wan, et al., 2012; T. Ohsawa, et al., 2002; T. Shino, et al., 2006; and E. Yoshida and T. Tanaka, 2003). In this device structure, the bottom portion of the channel region is in contact with the insulating layer of the SOI substrate, and is surrounded by the gate insulating layer and the element isolation insulating layer, enclosing the remaining channel region. In this structure, the channel region also has a floating body structure. As described above, it is only necessary for a dynamic flash memory element provided by the present embodiment to satisfy the condition that the channel region has a floating body structure. In addition, even with a structure in which fin transistors (see, for example, H. Jiang, N. Xu, B. Chen, L. Zeng1, Y. He, G. Du, X. Liu, and X. Zhang: “Experimental investigation of self heating effect (SHE) in multiple-fin SOI FinFETs,” Semicond. Sci. Technol. 29 115021 p. 7 (2014)) are formed on the SOI substrate, if the channel region has a floating body structure, the dynamic flash memory operations can be performed.

Although the reset voltages of the first and second selection gate lines SG1 and SG2, the bit line BL, and the source line SL described above are described as Vss, they may be set to different voltages.

In the present specification and claims, the meaning of “covering” in phrases like “the gate insulating layer, the gate conductor layer, or the like covers the channel or the like” includes cases where the entire channel is surrounded, as in SGT or GAA, cases where the channel is surrounded but with an un-surrounded portion, as in fin transistors, and cases where one overlaps with another flat one, as in planar-type transistors.

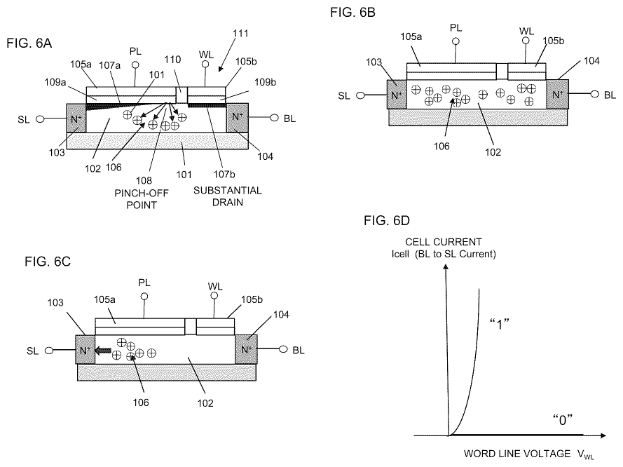

In FIG. 1, the first gate conductor layer 5a surrounds the entire first gate insulating layer 4a. In contrast, the first gate conductor layer 5a may be structured to surround a portion of the first gate insulating layer 4a in plan view. The first gate conductor layer 5a may be divided into at least two gate conductor layers, which are operated as gate electrodes of at least two plate line PLs. It is acceptable for the gate electrodes of the plate lines PL to be stacked in multiple layers, as illustrated in FIGS. 6A to 6D, or to be divided into left and right portions by splitting 360° in half. Similarly, the second gate conductor layer 5b may be divided into two or more portions, which are respectively operated as gate conductor electrodes synchronously or asynchronously. This makes it possible to perform dynamic flash memory operations. Then, in the case where the first gate conductor layer 5a is divided into two or more portions, at least one of the divided portions of the first gate conductor layer 5a performs the role of the first gate conductor layer 5a described above. Also, with regard to the divided portions of the second gate conductor layer 5b, at least one of the divided portions of the second gate conductor layer 5b performs the role of the second gate conductor layer 5b described above.

The conditions of voltages applied to the bit line BL, the source line SL, the first and second selection gate lines SG1 and SG2, and the plate line PL described above, and the voltage of the floating body are examples for performing basic operations of erasing operations, writing operations, and reading operations, and it is acceptable to use other voltage conditions as long as the basic operations of the present invention can be performed.

Although the case has been described using FIG. 1 where the configuration has three gate conductor layers of the first selection gate line SG1, the second selection gate line SG2, and the plate line PL, the configuration may be configured with two gate conductor layers by configuring the first selection gate line SG1 and the second selection gate line SG2 as one selection gate line SG. When the configuration is configured with two gate conductor layers as above, it is acceptable to provide either the plate line PL or the selection gate line SG on the bit line side.

The present embodiment has the following features.

### Features

In a dynamic flash memory cell according to the first embodiment of the present invention, voltages applied to the source line, the bit line, the selection gate line, and the plate line are controlled to perform a page erasing operation and a page writing operation, thereby changing the number of holes in the hole group within the semiconductor base to write and read logic storage data that is at least three-valued. For example, in the case of having four-valued logic storage data, the capacity of the memory device can be doubled as compared to the case of two-valued logic storage data. That is, an inexpensive memory device that halves the cost per bit can be provided.

### Other Embodiments

Although the Si pillar is formed in the present invention, it may be a semiconductor pillar made of a semiconductor material other than Si. This holds true for other embodiments of the present invention as well.

In addition, in FIG. 1, dynamic flash memory operations are also performed with a structure with the reversed polarity of the conductivity types of the N⁺ layers 3a and 3b, and the semiconductor base 7, which is a Player. In this case, the majority of carriers in the Si pillar 7, which is N type, are electrons. Thus, the group of electrons generated by impact ionization is stored in the semiconductor base 7, setting “1” state.

The present invention allows for various embodiments and modifications without departing from the broad spirit and scope of the invention. Furthermore, each of the aforementioned embodiments is for explaining one embodiment of the present invention and is not construed to limit the scope of the invention. The above-described embodiments and modifications can be optionally combined. Furthermore, it is within the technical scope of the present invention to omit some of the constituent elements of the above-described embodiments as necessary.

According to a memory device using a semiconductor element according to the present invention, a dynamic flash memory, which is a memory device using a high-density and high-performance SGT, is obtained.

What is claimed is:

1. A memory device using a semiconductor element in which, in plan view on a substrate, a page is composed of a plurality of memory cells arranged in a row direction, and a plurality of pages are arranged in a column direction,
wherein each memory cell included in each page comprises:
a semiconductor base that, on the base, stands vertically or extends horizontally with respect to the substrate;
a first impurity layer and a second impurity layer connected to both ends in an extension direction of the semiconductor base;
a gate insulating layer surrounding the semiconductor base; and
a first gate conductor layer and a second gate conductor layer that cover the gate insulating layer and that are arranged side by side;
the first impurity layer is connected to a source line, the second impurity layer is connected to a bit line, one of the first gate conductor layer or the second gate conductor layer is connected to a selection gate line, and the other is connected to a plate line;
voltages applied to the source line, the bit line, the selection gate line, and the plate line are controlled to perform a page erasing operation and a page writing operation;
within the semiconductor base, a hole group formed by an impact ionization phenomenon is retained; and
logic storage data that is at least three-valued is written and read.

2. The memory device using the semiconductor element according to claim 1, wherein the selection gate line includes a first selection gate line and a second selection gate line, and the first selection gate line and the second selection gate line hold the plate line therebetween.

3. The memory device using the semiconductor element according to claim 1, wherein the logic storage data is four-valued.

4. The memory device using the semiconductor element according to claim 1, wherein the voltage of the bit line is gradually increased during the page writing operation.

5. The memory device using the semiconductor element according to claim 1, wherein the voltage of one or both of the selection gate line and the plate line is gradually increased during the page writing operation.

6. The memory device using the semiconductor element according to claim 3, wherein the logic storage data which is four-valued is assigned in an order of “10”, “11”, “01”, and “00”, starting from a lower threshold voltage of the selection gate line.
